(19) United States
(12) Patent Application Publication
(10) Pub. No.: US 2026/0371501 A1
(43) Pub. Date: Nov. 19, 2026

(54) SNAP-FIT STRUCTURE AND WALL-MOUNTED DEVICE AND SECURITY DEVICE USING THE SAME

(71) Applicant: LITE-ON TECHNOLOGY COPORATION, Taipei (TW)

(72) Inventor: Cheng-Wen HUANG, taipei (TW)

(21) Appl. No.: 19/271,819

(22) Filed: Jul. 17, 2025

(30) Foreign Application Priority Data
May 14, 2025 (CN) 202520946543.6

(51) Int. Cl. H05K 5/02; F16B 2/22

(52) U.S. Cl. CPC H05K 5/0204; F16B 2/22

(57) ABSTRACT

A snap-fit structure is provided for assembling an electronic device. The snap-fit structure includes a first part and a second part, the first part includes a first latch and a second latch, and the second part includes a first position limiter and a second position limiter. The first latch and the second latch are respectively arranged on a first side and a second side of a bottom surface of the electronic device, and the first position limiter and the second position limiter are respectively arranged on a first installation side and a second installation side opposite to the bottom surface. The first and second latches are suitable for respectively snap-fitting with or moving away from the first and second position limiters when assembling/disassembling the electronic device.

### CROSS-REFERENCE TO RELATED APPLICATION

This application claims the benefit of People’s Republic of China application Serial No. 202520946543.6, filed May 14, 2025, the subject matter of which is incorporated herein by reference.

### BACKGROUND OF THE INVENTION

### Field of the Invention

The invention relates in general to a tool-free installation device, and more particularly to a snap-fit structure and a wall-mounted device and a security device using the same.

### Description of the Related Art

Compared to installation methods that use tools for assembly, tool-free installation methods (such as methods that rely on a snap-fit structure) are faster, so that users can quickly assemble an electronic device on a mounting surface (such as a wall) and/or remove the electronic device from the mounting surface.

In many cases, electronic devices may have to be removed from the mounting surface, such as during maintenance of components inside the electronic devices or replacement of batteries. However, users do not know how to install the electronic devices because there are too many parts to assemble/disassemble or the assembly steps are too complicated. In addition, after the electronic device is disassembled using tools, the disassembly tool may be lost due to improper storage, resulting in a situation where there is no tool available and the device cannot be disassembled next time. Therefore, there is a need to improve the installation means of electronic devices.

### SUMMARY OF THE INVENTION

The invention is directed to a snap-fit structure and a wall-mounted device and a security device using the same, which do not require the use of tools for assembly and disassembly.

According to one aspect of the present invention, a snap-fit structure is provided for assembling an electronic device. The snap-fit structure includes a first part and a second part, the first part includes a first latch and a second latch, and the second part includes a first position limiter and a second position limiter. The first latch and the second latch are respectively arranged on a first side and a second side of a bottom surface of the electronic device, and the first position limiter and the second position limiter are respectively arranged on a first installation side and a second installation side opposite to the bottom surface. The first and second latches are suitable for respectively snap-fitting with or moving away from the first and second position limiters when assembling/disassembling the electronic device.

According to one aspect of the present invention, a wall-mounted device is provided, including an electronic device and a wall-mounted part. The electronic device includes a housing and a pivot, and the pivot is arranged on the bottom surface of the housing. The wall-mounted part is used to assemble the electronic device on a mounting surface. The pivot is sleeved in a pivot hole of the wall-mounted part, and the housing is rotatable relative to the wall-mounted part so that the electronic device moves from an assembly position to a disassembly position or from the disassembly position to the assembly position.

According to one aspect of the present invention, a security device is provided, which is arranged on a mounting surface. The security device includes an electronic device, a wall-mounted part and at least one snap-fit structure. The electronic device includes a visual part and a voice part. The wall-mounted part is used to assemble the electronic device on the mounting surface. The snap-fit structure includes a first part and a second part. The first part includes at least one latch arranged on at least one side of a bottom surface of the electronic device, and the latch has an insert part or a protrusion. The second part includes at least one position limiter disposed on at least one mounting side of the wall-mounted part opposite to the bottom surface, and the position limiter has an insertion hole for accommodating the insert and/or a positioning portion for positioning the protrusion. The electronic device is rotatable relative to the wall-mounted part so that the electronic device moves from an assembly position to a disassembly position or from the disassembly position to the assembly position.

According to one aspect of the present invention, an installation method is provided for assembling an electronic device. The installation method includes the following steps. A wall-mounted part is fixed to a mounting surface. A position limiter is provided on at least one mounting side of the wall-mounted part, and a latch is provided on at least one side of the electronic device relative to the position limiter. When assembling/disassembling the electronic device, the electronic device is rotated, and the latch is snap-fitted with or separated from the position limiter, so that the electronic device is moved from an assembly position to a disassembly position or from the disassembly position to the assembly position.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIGS. 1A and 1B are exploded schematic diagrams of the front and back views of the wall-mounted device according to an embodiment of the present invention, respectively.

FIG. 2 is a schematic diagram of a wall-mounted part according to an embodiment of the present invention.

FIGS. 3A and 3B are schematic diagrams of the installation operation method of the wall-mounted device according to an embodiment of the present invention, respectively.

FIGS. 4A and 4B are schematic diagrams of the disassembly operation method of the wall-mounted device according to an embodiment of the present invention, respectively.

FIGS. 5A-5C are schematic cross-sectional diagrams of the wall-mounted device during the installation, respectively.

FIG. 6 is an exploded schematic diagram of a back view of the wall-mounted device according to an embodiment of the present invention.

### DETAILED DESCRIPTION OF THE INVENTION

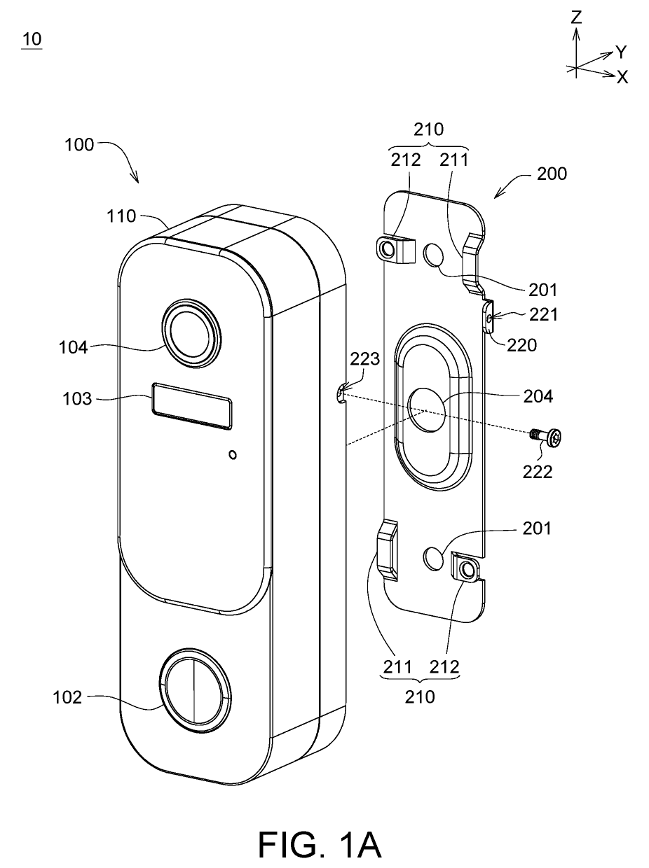

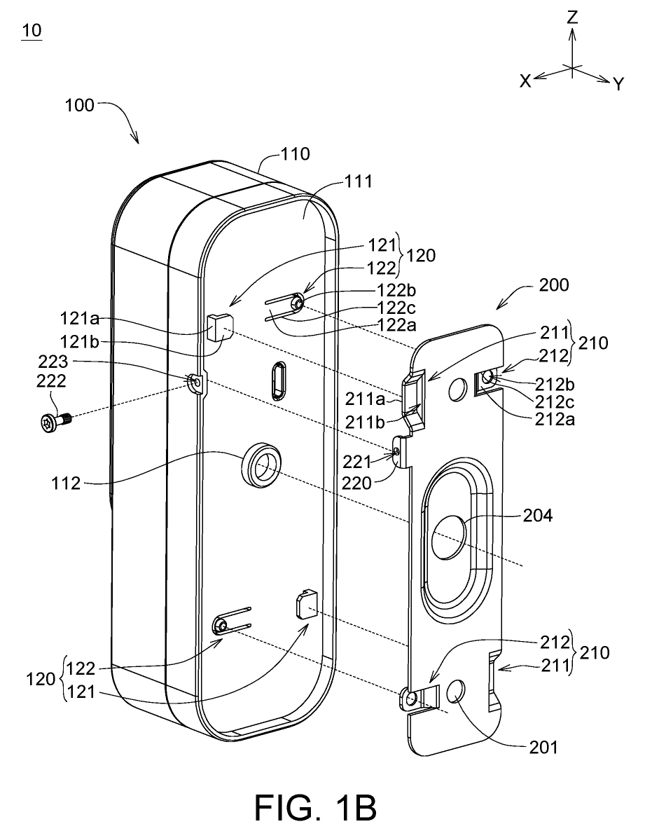

Referring to FIGS. 1A and 1B, schematic diagrams of the front and back views of a wall-mounted device 10 according to an embodiment of the present invention are respectively illustrated. The wall-mounted device 10 is, for example, a security device, which may include a door control device, a doorbell device and/or an image monitoring device. The wall-mounted device 10 is set on a door or a wall, and the wall-mounted device 10 has, for example, an operable part (such as a doorbell button 102), a voice part (such as an intercom 103) and/or a visual part (such as a camera 104) and other components, as shown in FIG. 1A. When someone visits, the host can communicate with the visitor through the intercom 103 and the visitor's image can be shown. If there is a suspicious person watching or staying nearby, the surrounding images can also be monitored through the camera 104 or a warning sound can be issued through the intercom 104. In this way, in one embodiment, the wall-mounted device 10 can remotely monitor the home environment and record real-time images to improve home safety.

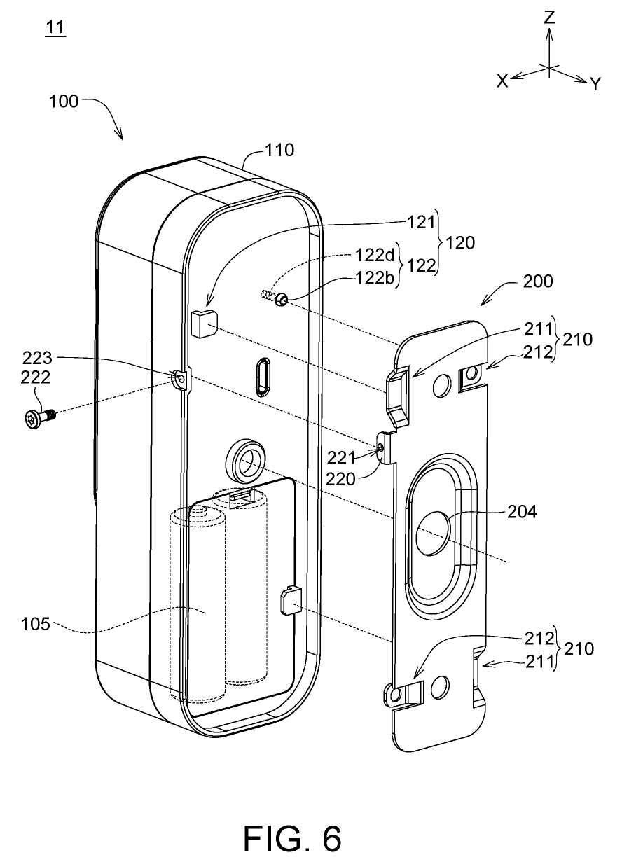

Generally speaking, the wall-mounted device 10 is designed to be detachable to facilitate installation and uninstallation. The wall-mounted device 10 is provided with a battery 105 (see FIG. 6) inside or supplied by an external power source. When the battery 105 is out of power or the internal components fail, the wall-mounted device 10 has to be disassembled from the installation surface. Therefore, in one embodiment, the wall-mounted device 10 is designed to be tool-free to install, which can avoid the situation where the disassembly tool may be lost due to improper storage, resulting in no tools available or the disassembly cannot be performed.

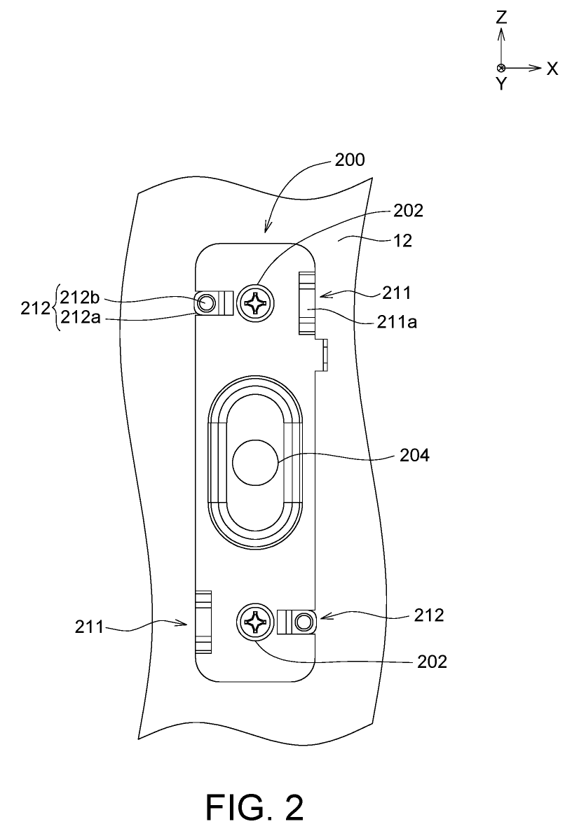

Referring to FIG. 1B, the wall-mounted device 10 includes an electronic device 100 and a wall-mounted part 200. The electronic device 100 can be assembled on a mounting surface 12 (see FIG. 2) through the wall-mounted part 200. The mounting surface 12 is, for example, a door, a wall or other supporters. The electronic device 100 may include a housing 110 and a pivot 112. The pivot 112 is disposed on the bottom surface 111 of the housing 110, and the position of the pivot 112 is opposite to the position of a pivot hole 204 of the wall-mount part 200, so that the pivot 112 can be mounted on the wall-mount part 200 and can rotate relative to the pivot hole 204.

In addition, as shown in FIGS. 1A and 1B, the wall-mount part 200 may include at least one opening 201 (two are shown in the figure), and the opening 201 can allow a latch 202 (such as a screw, see FIG. 2) to pass through, so that the wall-mount part 200 can be fixed on the mounting surface 12.

Referring to FIGS. 1A and 1B, in order to enable the electronic device 100 to be installed on the wall-mount part 200 without tools, at least one set of first parts 120 is disposed on the bottom surface 111 of the housing 110 of the electronic device 100, and at least one set of second parts 210 is disposed on the wall-mount part 200. The number of the first parts 120 can be two, and the number of the second parts 210 can be two, but the present invention is not limited thereto. As shown in FIG. 1B, the first set of first parts 120 is arranged on one side of the pivot 112, and the second set of first parts 120 is arranged on the other side of the pivot 112. In addition, the first set of second parts 210 is arranged on one side of the pivot hole 204, and the second set of second parts 210 is arranged on the other side of the pivot hole 204. The first set of first parts 120 cooperates with the first set of second parts 210 to form a first set of snap-fit structures, and the second set of first parts 120 cooperates with the second set of second parts 210 to form a second set of snap-fit structures. However, in other embodiments, only one set of snap-fit structures may also be arranged on either side of the pivot 112 and the pivot hole 204. The first and second set of snap-fit structures can be the same or similar structures, and the following embodiments only describe one set of snap-fit structures in detail.

Referring to FIG. 1B, the first part 120 includes a first latch 121 and a second latch 122. The first latch 121 and the second latch 122 are respectively disposed on a first side and a second side, such as a left side and a right side, of the bottom surface 111 of the electronic device 100. The first latch 121, for example, has a vertical section 121a and a horizontal section 121b. The vertical section 121a and the horizontal section 121b are connected to form an L-shaped structure. However, the first latch 121 may also be in other shapes, not limited to the L-shape. In addition, the second latch 122, for example, is an elastic member, which may include an elastic arm 122a and a protrusion 122b. The protrusion 122b is located at one end of the elastic arm 122a, and the protrusion 122b can move relative to the bottom surface 111 through the elastic arm 122a. In detail, the first end of the elastic arm 122a is fixed to a slot sidewall 122c of the bottom surface 111, and the second end of the elastic arm 122a extends a horizontal distance from the first end along the X-axis direction and is not connected to the slot sidewall 122c, so that the second end of the elastic arm 122a can have a degree of freedom degree of movement relative to the first end in the normal direction (Y-axis direction) of the bottom surface 111. The protrusion 122b is arranged at the second end of the elastic arm 122a, so the protrusion 122b also has a freedom degree of movement in the Y-axis direction.

In another embodiment, the protrusion 122b can have a freedom degree of movement in the Y-axis direction through other means. For example, the protrusion 122b can be a soft elastic material, and when the protrusion 122b is pressed, it can generate a slight compression through its own elasticity. In addition, referring to FIG. 6, an exploded schematic diagram of a back view of the wall-mounted device 11 according to an embodiment of the present invention is illustrated. When the protrusion 122b is made of a hard material, an elastic body 122d (such as a spring) can be added to the bottom of the protrusion 122b so that the protrusion 122b has a freedom degree of movement in the Y-axis direction.

In addition, the second part 210 includes a first position limiter 211 and a second position limiter 212. The first position limiter 211 and the second position limiter 212 are respectively arranged on the first installation side and the second installation side of the wall-mounted part 200, such as the left side and the right side. The first position limiter 211 is arranged opposite to the first latch 121, and the second position limiter 212 is arranged opposite to the second latch 122. The first position limiter 211, for example, has a bridging section 211a, and both ends of the bridging section 211a are connected to the wall-mounted part 200 to form an arch structure. In one embodiment, the bridging section 211a can be directly stamped from the plate of the wall-mounted part 200 to form an insertion hole 211b between the bridging section 211a and the wall-mounted part 200. Therefore, when the electronic device 100 is installed, the horizontal section 121b (i.e., the insert part) of the first latch 121 can be inserted into the insertion hole 211b, and the vertical section 121a of the first latch 121 and the bridging section 211a are snap-fitted in the X-axis direction parallel to the bottom surface 111, so that the electronic device 100 is positioned at an assembly position.

In addition, the second position limiter 212 is, for example, an elastic member, which has a spring sheet 212a and a positioning portion 212b. The positioning portion 212b is located at one end of the spring sheet 212a, and the positioning portion 212b can move relative to the wall-mounted part 200 through the spring sheet 212a. In detail, the first end of the spring sheet 212a is fixed to a slot sidewall 212c of the wall-mount part 200, and the second end of the spring sheet 212a extends a horizontal distance from the first end along the X-axis direction and is not connected to the slot sidewall 122c, so that the second end of the spring sheet 212a can have a freedom degree of movement relative to the first end in the normal direction (Y-axis direction) of the wall-mount part 200. The positioning portion 212b is disposed at the second end of the spring sheet 212a, for example, a notch, and the positioning portion 212b also has a freedom degree of movement in the Y-axis direction.

In another embodiment, the positioning portion 212b can have a freedom degree of movement in the Y-axis direction by other means. For example, the positioning portion 212b can be a soft elastic material, and when the positioning portion 212b is pressed, it can generate a slight compression through its own elasticity. In addition, when the positioning portion 212b is made of a hard material, an elastic body (such as a spring) can be added to the bottom of the positioning portion 212b so that the positioning portion 212b has a freedom degree of movement in the Y-axis direction.

In one embodiment, the spring sheet 212a and the positioning portion 212b can be directly stamped from the plate of the wall-mounted part 200 to make the spring sheet 212a and the positioning portion 212b on the wall-mounted part 200. When the electronic device 100 is installed, the protrusion 122b of the second latch 122 is engaged in the normal direction (Y-axis direction) of the bottom surface 111 to position the electronic device 100 in an assembly position.

In one embodiment, the first position limiter 211 is disposed opposite to and aligned with the first latch 121, and the second position limiter 212 is disposed opposite to and aligned with the second latch 122. Therefore, the first latch 121 and the second latch 122 can be snap-fitted with or separated from the first and second position limiters 211 and 212 respectively when assembling/disassembling the electronic device 100. In another embodiment, the first position limiter 211 and the first latch 121 are interchangeable, and the second position limiter 212 and the second latch 122 are interchangeable. For example, the first position limiter 211 may be an L-shaped structure, and the first latch 121 can be an arched structure; or the second position limiter 212 may have a protrusion similar to the protrusion 122b, and the second latch 122 can have a positioning portion similar to the positioning portion 212b. The present invention is not limited thereto.

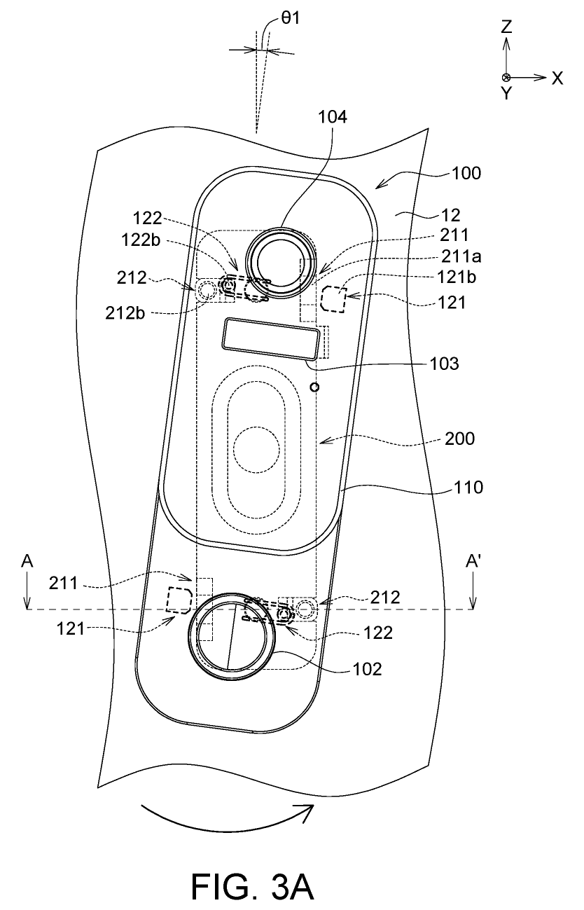

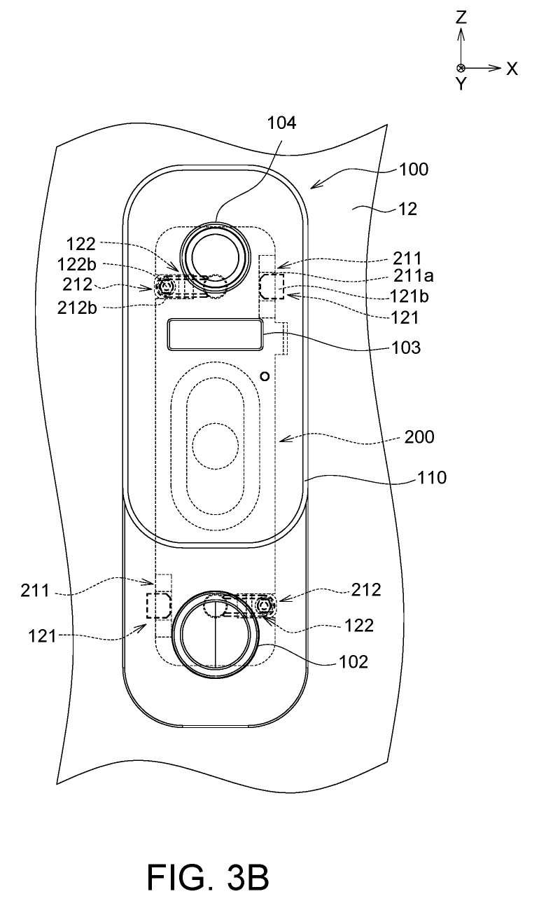

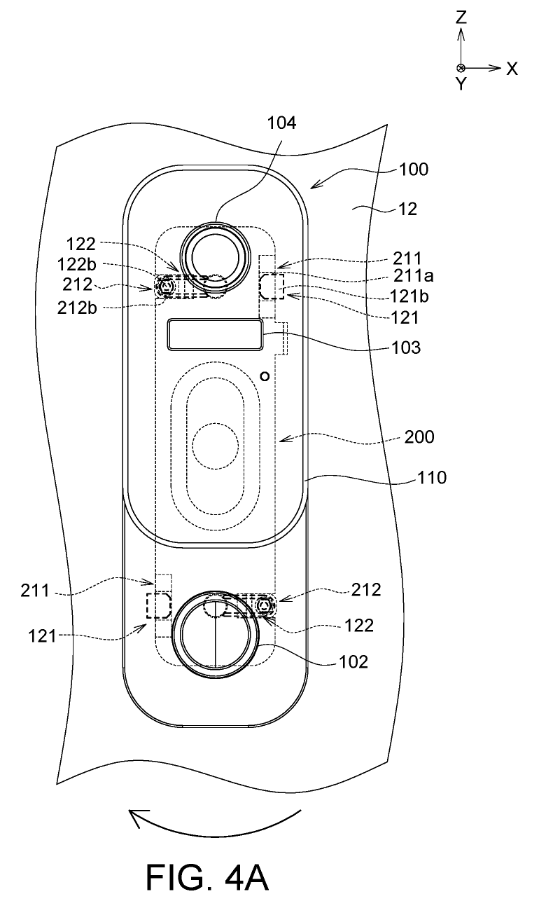

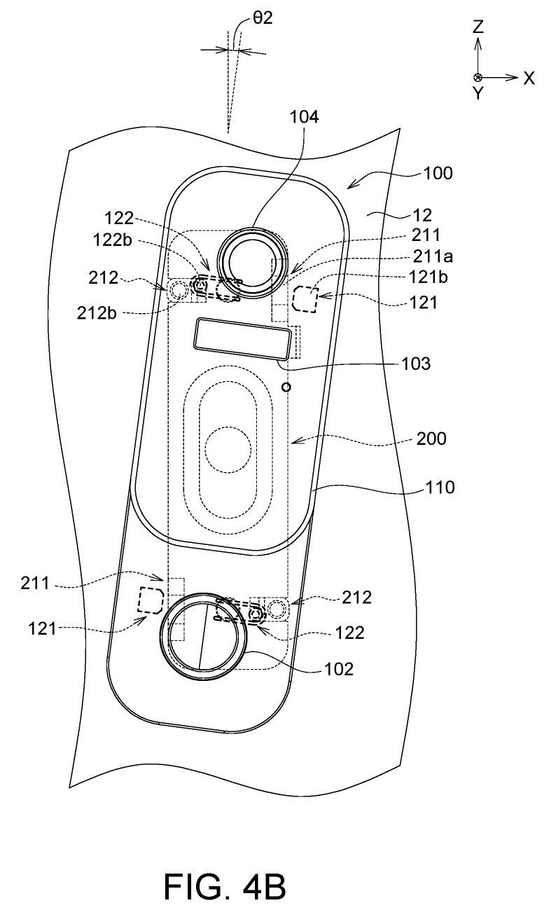

Referring to FIGS. 2, 3A, 3B, 4A and 4B, FIG. 2 is a schematic diagram of a wall-mounted part 200 according to an embodiment of the present invention, FIGS. 3A and 3B are respectively schematic diagrams of the assembly operation method of the wall-mounted device 10 according to an embodiment of the present invention, and FIGS. 4A and 4B are respectively schematic diagrams of the disassembly operation method of the wall-mounted device 10 according to an embodiment of the present invention.

The installation method of the wall-mounted device 10 includes the following steps. First, the wall-mounted part 200 is fixed to a mounting surface 12 (such as a door, a wall or other supporter). A first position limiter 211 (such as an arch structure) is provided on at least one mounting side of the wall-mounted part 200, and a second position limiter 212 (such as a spring sheet 212a) is provided on at least one mounting side of the wall-mounted part 200. As described above, a positioning portion 212b is provided at one end of the spring sheet 212a, and the positioning portion 212b is, for example, a notch or other structure. In addition, a first latch 121 (e.g., an L-shaped structure) is disposed on at least one side of the electronic device 100 relative to the first position limiter 211, and a second latch 122 (e.g., an elastic arm 122a) is disposed on at least one side of the electronic device 100 relative to the second position limiter 212. One end of the elastic arm 122a is provided with a protrusion 122b, and the shape of the protrusion 122b matches that of the positioning portion 212b, so that the protrusion 122b is positioned in the recess of the positioning portion 212b. In FIGS. 3A and 3B, when the electronic device 100 is assembled, the electronic device 100 is first rotated relative to the vertical axis (Z axis) by a first angle θ1 (e.g., 20 to 30 degrees), and the pivot 112 of the electronic device 100 is inserted into the pivot hole 204 of the wall-mounted part 200. Next, the electronic device 100 is rotated counterclockwise so that the first latch 121 of the electronic device 100 can be snap-fitted with the first position limiter 211 of the wall-mount part 200, and the second latch 122 of the electronic device 100 can be snap-fitted with the second position limiter 212 of the wall-mount part 200. In FIGS. 4A and 4B, when the electronic device 100 is disassembled, the electronic device 100 is first rotated clockwise by a second angle θ2 (e.g., 20 to 30 degrees) relative to the vertical axis (Z axis), so that the first latch 121 of the electronic device 100 can be separated from the first position limiter 211 of the wall-mount part 200, and the second latch 122 of the electronic device 100 can be separated from the second position limiter 212 of the wall-mount part 200. Next, the pivot 112 of the electronic device 100 is pulled out from the pivot hole 204 of the wall-mount part 200, and the electronic device 100 can be disassembled without using tools.

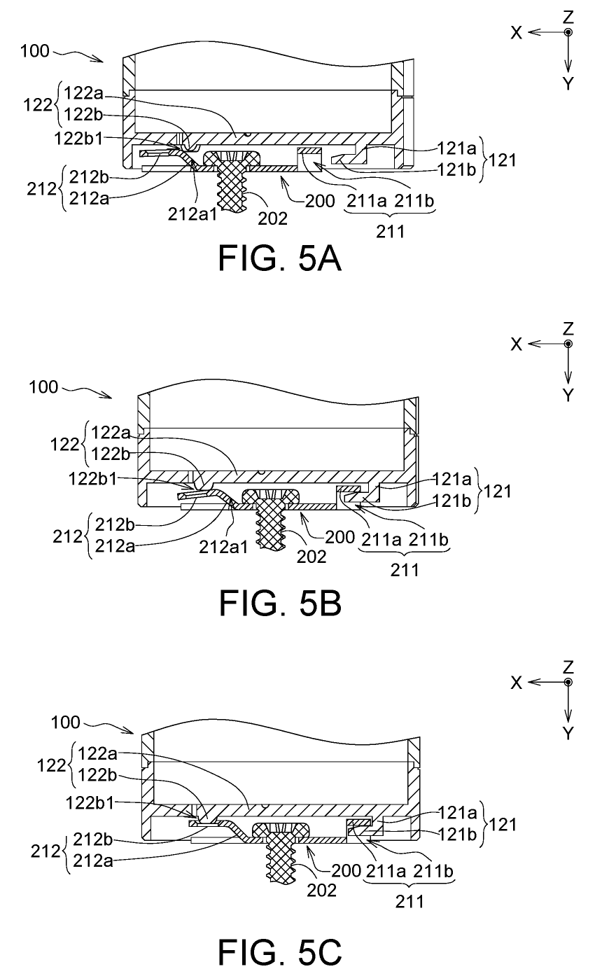

Referring to FIGS. 5A-5C, schematic cross-sectional diagrams of the wall-mounted device 10 during the installation are illustrated. From top to bottom, FIG. 5A is a cross-sectional diagram of the electronic device 100 in FIG. 3A at the disassembly position along the line A-A', FIG. 5B is a schematic diagram of the electronic device 100 in FIG. 5A rotating counterclockwise, and FIG. 5C is a cross-sectional diagram of the electronic device 100 in FIG. 5B at the assembly position along the line A-A'. As can be seen from the description of FIGS. 5A-5C, when the electronic device 100 is moved from the disassembly position to the assembly position, the protrusion 122b located outside the positioning portion 212b abuts against one side of the spring sheet 212a, and the protrusion 122b and the spring sheet 212a respectively have a contact inclined surface 122b1 and a contact inclined surface 212a1, the two contact inclined surfaces 122b1, 212a1 abut against each other, and through the rotation of the electronic device 100, the protrusion 122b and the spring sheet 212a push against each other and each produces a displacement, so that the protrusion 122b can enter the positioning portion 212b through the deformation of the spring sheet 212a and/or the elastic arm 122a. On the contrary, in FIG. 5C, when the electronic device 100 is moved from the assembly position to the disassembly position, the protrusion 122b and the spring sheet 212a push against each other and generate displacement through the rotation of the electronic device 100, so that the protrusion 122b positioned in the positioning portion 212b can be moved away from the positioning portion 212b through the deformation of the spring sheet 212a and/or the elastic arm 122a, so as to facilitate the disassembly of the electronic device 100.

In addition, referring to FIGS. 1A and 1B, the wall-mounted device 10 may include a fixing structure, which includes at least one fixing sheet 220 and at least one fixing member 222. The fixing sheet 220 is, for example, fixedly disposed on one side of the wall-mounted part 200 and extends along the Y-axis direction to one side of the electronic device 100. The electronic device 100 is provided with a positioning hole 223 relative to the fixing sheet 220, and the fixing member 222 can pass through the through hole 221 of the fixing sheet 220 and be locked in the positioning hole 223 to prevent the electronic device 100 from being stolen. The fixing member 222 is, for example, a screw or other locking element. Since the electronic device 100 cannot be disassembled in the locked state, the anti-theft performance is improved.

In summary, the snap-fit structure of the present embodiment and the wall-mounted device and security device using the same can be arranged in a rotatable manner relative to the wall-mounted part so that the electronic device can be moved from the disassembly position to the assembly position or from the assembly position to the disassembly position. Therefore, the electronic device can be assembled and disassembled, which is more convenient to use and does not require the use of disassembly tools.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A snap-fit structure for assembling an electronic device, the snap-fit structure comprising:
a first part, comprising a first latch and a second latch, the first latch and the second latch are respectively arranged on a first side and a second side of a bottom surface of the electronic device; and
a second part, comprising a first position limiter and a second position limiter, the first position limiter and the second position limiter are respectively arranged on a first mounting side and a second mounting side opposite to the bottom surface, the first latch and the second latch are respectively adapted to be snap-fitted with or away from the first position limiter and the second position limiter when assembling/disassembling the electronic device.

2. The snap-fit structure as claimed in claim 1, wherein the first latch and the first position limiter are snap-fitted in an axial direction parallel to the bottom surface.

3. The snap-fit structure as claimed in claim 2, wherein one of the first latch and the first position limiter includes an insert part, and the other of the first latch and the first position limiter includes an insertion hole for accommodating the insert part.

4. The snap-fit structure as claimed in claim 1, wherein the second latch and the second position limiter are snap-fitted in a normal direction of the bottom surface.

5. The snap-fit structure as claimed in claim 4, wherein one of the second latch and the second position limiter includes a protrusion, and the other of the second latch and the second position limiter includes a positioning portion, and a shape of the protrusion matches a shape of the positioning portion.

6. The snap-fit structure as claimed in claim 5, wherein at least one of the protrusion and the positioning portion has a freedom degree of movement in the normal direction of the bottom surface.

7. A wall-mounted device, comprising:
an electronic device, comprising a housing and a pivot, the pivot being disposed on a bottom surface of the housing; and
a wall-mounted part, for assembling the electronic device on a mounting surface, wherein the pivot is sleeved in a pivot hole of the wall-mounted part, and the housing is rotatable relative to the wall-mounted part, so that the electronic device moves from an assembly position to a disassembly position or from the disassembly position to the assembly position.

8. The wall-mounted device as claimed in claim 7, wherein when the electronic device rotates a first angle relative to the wall-mounted part, the electronic device moves from the disassembly position to the assembly position, and when the electronic device rotates a second angle in an opposite direction relative to the wall-mounted part, the electronic device moves from the assembly position to the disassembly position.

9. A security device, arranged on a mounting surface, comprising:
an electronic device, comprising a visual part and a voice part;
a wall-mounted part configured to assemble the electronic device on the mounting surface; and
at least one snap-fit structure, comprising a first part and a second part,
wherein the first part comprises at least one latch, the at least one latch is arranged on at least one side of a bottom surface of the electronic device, the latch has at least one of an insert part and a protrusion;
the second part comprises at least one position limiter, the at least one position limiter is arranged on at least one mounting side of the wall-mounted part opposite to the bottom surface, the position limiter has an insertion hole for accommodating the insert part or a positioning part for positioning the protrusion or has the insertion hole and the positioning part,
wherein the electronic device is rotatable relative to the wall-mounted part, so that the electronic device moves from an assembly position to a disassembly position or from the disassembly position to the assembly position.

10. The security device as claimed in claim 9, wherein the insert part and the insertion hole are located in an axial direction parallel to the bottom surface.

11. The security device as claimed in claim 9, wherein the protrusion and the positioning portion are arranged in an axial direction parallel to a normal direction of the bottom surface.

12. The security device as claimed in claim 9, wherein the protrusion is arranged on an elastic body or an elastic arm, and the positioning portion is arranged on a spring sheet.

13. An installation method, comprising:
fixing a wall-mounted part to a mounting surface, wherein a position limiter is provided on at least one mounting side of the wall-mounted part, and a latch is provided on at least one side of the electronic device relative to the position limiter; and
when assembling/disassembling the electronic device, the electronic device is rotated, and the latch is snap-fitted with or separated from the position limiter, so that the electronic device is moved from an assembly position to a disassembly position or from the disassembly position to the assembly position.

14. The installation method as claimed in claim 13, wherein when the electronic device rotates a first angle relative to the wall-mounted part, the electronic device moves from the disassembly position to the assembly position, and when the electronic device rotates a second angle in the opposite direction relative to the wall-mounted part, the electronic device moves from the assembly position to the disassembly position.

15. The installation method as claimed in claim 13, wherein each of the latch and the position limiter has a contact inclined surface, the two contact inclined surfaces abut against each other when assembling/disassembling the electronic device, and through the rotation of the electronic device, the electronic device moves from the assembly position to the disassembly position or from the disassembly position to the assembly position.
